(19) United States
(12) Patent Application Publication
(10) Pub. No.: US 2016/0085326 A1
(43) Pub. Date: Mar. 24, 2016

(54) CONDUCTIVE LAMINATE, TOUCH PANEL AND ELECTRONIC DEVICE USING THE CONDUCTIVE LAMINATE, AND METHOD FOR MAKING THE CONDUCTIVE LAMINATE

(71) Applicants: INTERFACE OPTOELECTRONIC (SHENZHEN) CO., LTD., SHENZHEN (CN); GENERAL INTERFACE SOLUTION LIMITED, Miaoli County (TW)

(72) Inventors: CHIN-YANG WU, Zhubei (TW); TEN-HSING JAW, Zhubei (TW); CHIU-CHI CHEN, Zhubei (TW)

(21) Appl. No.: 14/555,700

(22) Filed: Nov. 28, 2014

(30) Foreign Application Priority Data
Sep. 18, 2014 (CN) 201410476729.6

(51) Int. Cl. G06F 3/041; H05K 3/00; H05K 3/18; H05K 1/02; H05K 1/09

(52) U.S. Cl. CPC G06F 3/041; H05K 1/0296; H05K 1/092; H05K 3/181; H05K 3/0058; H05K 2203/085; G06F 2203/04102

(57) ABSTRACT

A conductive laminate includes a base layer, an insulative layer on the base layer, an ink layer having a latticed structure on the insulative layer, and a conductive metal layer having a latticed structure on the ink layer. The insulative layer contains a transparent and insulative adhesive.

### FIELD

The subject matter herein generally relates to a conductive laminate, a touch panel and an electronic device using the conductive laminate, and a method for making the conductive laminate.

### BACKGROUND

Today, more and more electronic devices (such as mobile phones, tablet personal computers, electronic books, and personal digital assistants (PDAs) use touch panels. Touch panels commonly include a transparent conductive laminate.

### BRIEF DESCRIPTION OF THE DRAWINGS

Implementations of the present technology will now be described, by way of example only, with reference to the attached figures.

FIG. 1 is an isometric view of a first exemplary embodiment of a conductive laminate.

FIG. 2 is a cross-sectional view of the conductive laminate of FIG. 1.

FIG. 3 is a diagrammatic view of a printing process for forming the conductive laminate of FIG. 1.

FIG. 4 is an isometric view of an electronic device using the conductive laminate of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series, and the like.

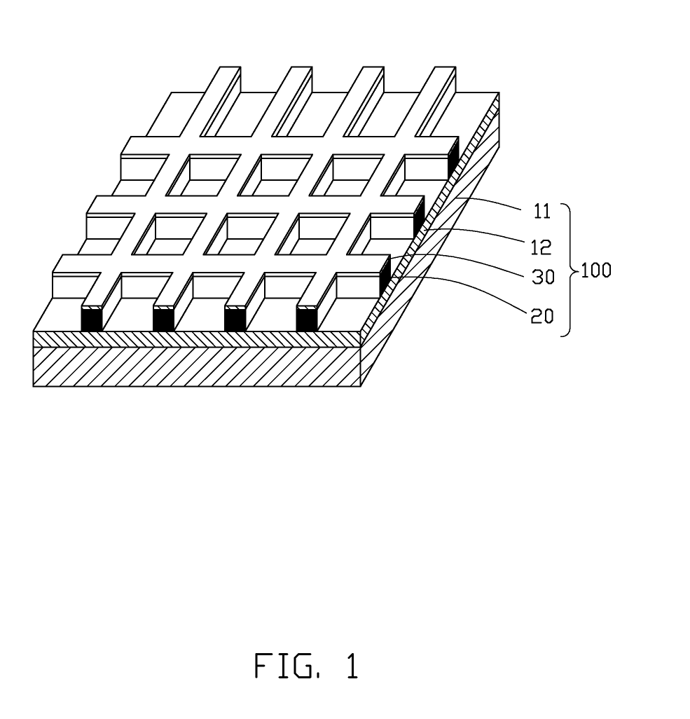

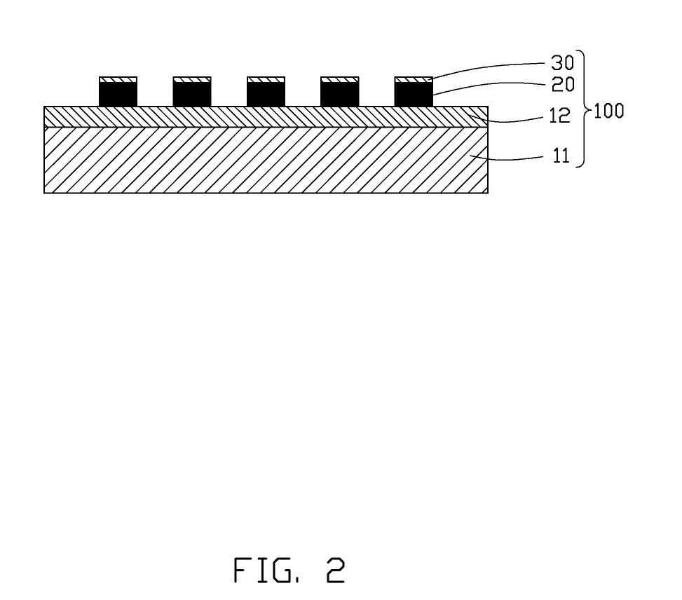

FIGS. 1 and 2 illustrate a conductive laminate 100 according to a first exemplary embodiment. The conductive laminate 100 includes a base layer 11, an insulative layer 12 formed on the base layer 11, an ink layer 20 formed on the insulative layer 12, and a metal layer 30 formed on the ink layer 20. The ink layer 20 and the metal layer 30 form a latticed structure.

The base layer 11 is made of a transparent and flexible material. The transparent and flexible material can be polyethylene terephthalate, polyethylene naphthalate, polyolefin, vinyl ester resins, poly (ether-ether-ketone), polysulfone, polyether sulphone, polycarbonate, polyamide, polyimide, or acrylic resin, for example.

The insulative layer 12 contains a transparent and insulative adhesive. The transparent and insulative adhesive can be thermoplastic or UV-curable. The insulative layer 12 is transparent. The insulative layer 12 can have a thickness of about 3 μm to about 50 μm.

The ink layer 20 is transparent and contains a transparent ink. The transparent ink can be a conductive ink or a non-conductive ink. The conductive ink contains at least one type of metal particles selected from the group consisting of gold particles, silver particles, copper particles, and palladium particles. The non-conductive ink can be a tin-palladium colloid ink, a palladium ion ink, or an ink containing copper oxide. The ink is not limited to the above-described inks, that is, other kinds of ink can be used. The ink layer 20 forms a latticed structure; therefore, the ink layer 20 is consisted of a plurality of interlaced ink strips having a width of less than 10 μm. The ink layer 20 can have a thickness of about 0.1 μm to about 50 μm.

The metal layer 30 is conductive. The metal layer 30 can be made of gold, silver, copper, palladium, nickel, and any combination thereof. The metal layer 30 can have a thickness of about 0.1 μm to about 20 μm. As the metal layer 30 is thin, the metal layer 30 is also transparent. Since the base layer 11, the insulative layer 12, the ink layer 20, and the metal layer 30 are all transparent, as a whole, the conductive laminate 100 is also transparent. The conductive laminate 100 has a good light transmission.

In order to improve the bond between the ink layer 20 and the insulative layer 12, an adhesive layer (not shown) can be formed between the insulative layer 12 and the ink layer 20. The insulative layer 12 can be surface treated to be rough after being formed on the base layer 11. The adhesive layer 12 can be made of an epoxy resin adhesive, a polyurethane adhesive, or a polymethyl methacrylate adhesive. The surface treatment can be performed by corona discharge treatment, plasma treatment, flame treatment, oxidation treatment, or acid erosion.

A method for making the conductive laminate 100 can include the following steps:

First, a base layer 11 is provided. The base layer 11 is made of a transparent and flexible material. The transparent and flexible material can be polyethylene terephthalate, polyethylene naphthalate, polyolefin, vinyl ester resins, poly(ether-ether-ketone), polysulfone, polyether sulphone, polycarbonate, polyamide, polyimide, or acrylic resin, for example.

Then, an insulative layer 12, containing a transparent and insulative adhesive, is formed on the base layer 11. The insulative layer 12 can be formed by any known methods in the field, such as coating and spraying, etc. The insulative layer 12 can have a thickness of about 3 μm to about 50 μm. The transparent and insulative adhesive can be thermoplastic or UV-curable.

Next, an ink layer 20 is formed in a latticed structure on the insulative layer 12. The ink layer 20 can have a thickness of about 0.1 μm to about 50 μm. The ink layer 20 can contain a transparent conductive ink or a transparent non-conductive ink. The conductive ink contains at least one type of metal particles selected from the group of consisting of gold particles, silver particles, copper particles, and palladium particles. The non-conductive ink can be a tin-palladium colloid ink, a palladium ion ink, or an ink containing copper oxide.

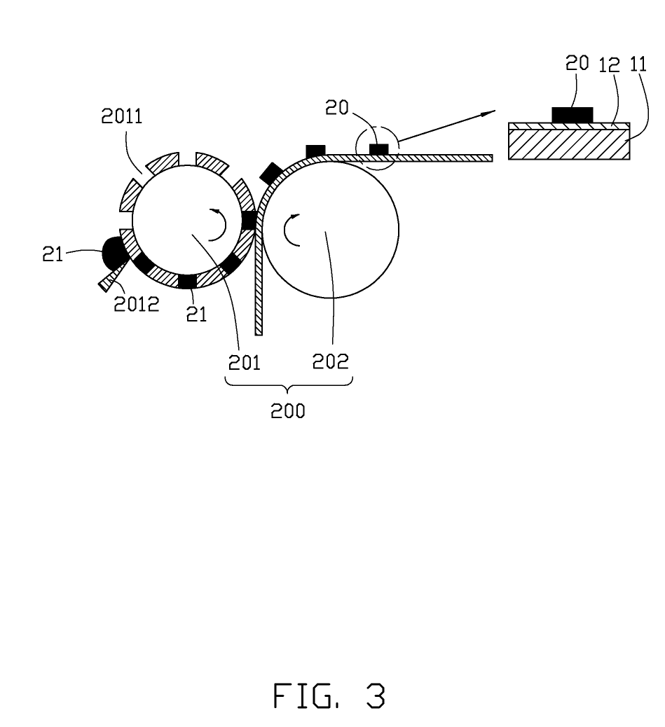

In this embodiment, the ink layer 20 is formed on the insulative layer 12 by gravure printing. FIG. 3 illustrates the printing process for forming the ink layer 20 on the insulative layer 12. As shown in FIG. 3, a gravure printing device 200 is provided, which includes a first roller 201 and a second roller 202. The surface of the first roller 201 defines a plurality of interlaced grooves 2011 which form a latticed structure. The surface of the second roller 202 is smooth. A gap is formed between the first roller 201 and the second roller 202, and the workpiece to be printed (such as insulative layer 12 coupled with the base layer 11) can pass through the gap. The grooves 2011 of the first roller 201 are filled with ink 21 during rolling. A scraper 2012 is provided for the first roller 201 to remove the excess ink on the surface of the first roller 201.

When both the first roller 201 and the second roller 202 rotate relative to each other, the insulative layer 12 coupled with the base layer 11 pass through the gap, which allows the ink 21 in the grooves 2011 to be printed on the surface of the insulative layer 12. Then the ink layer 20 having a latticed structure is formed on the insulative layer 12.

A metal layer 30 is formed in a latticed structure on the ink layer 20. The metal layer 30 can be formed to have a thickness of about 0.1 μm to about 20 μm. When the ink layer 20 contains the above-described conductive ink, the metal layer 30 can be formed by heating the conductive ink of the ink layer 20 at a temperature of about 80° C. to about 200° C. During the heating process, some components (such as solvent) in the conductive ink evaporate and dissipate such that the metal particles accumulate and expose to form the metal layer 30. In this case, the metal layer 30 can be made of gold, silver, copper, palladium, and any combination thereof.

When the ink layer 20 contains the above-described non-conductive ink, the metal layer 30 can be formed on the ink layer 20 by an electroless plating process. In this case, the metal layer 30 can be made of silver, copper, nickel, and any combination thereof. For example, when the metal layer 30 is made of copper, the electroless plating process can use a solution containing copper sulfate and other substances, such as a reductant, a chelating agent, or any other suitable reagent.

The metal layer 30 can also be formed by other known coating methods in the field, such as vacuum deposition. In this case, the ink layer 20 can contain other kinds of ink. During the vacuum depositing process of the metal layer 30, the surface of the insulative layer 12 not covered by the ink layer 20 should be masked.

In order to improve the bond between the ink layer 20 and the insulative layer 12, the method for making the conductive laminate 100 can also include forming an adhesive layer (not shown) between the insulative layer 12 and the ink layer 20 or surface treating the insulative layer 12 to be rough after the insulative layer 12 is formed on the base layer 11. The adhesive layer 12 may be made of an epoxy resin adhesive, a polyurethane adhesive, or a polymethyl methacrylate adhesive. The surface treatment can be performed by corona discharge treatment, plasma treatment, flame treatment, oxidation treatment, or acid erosion.

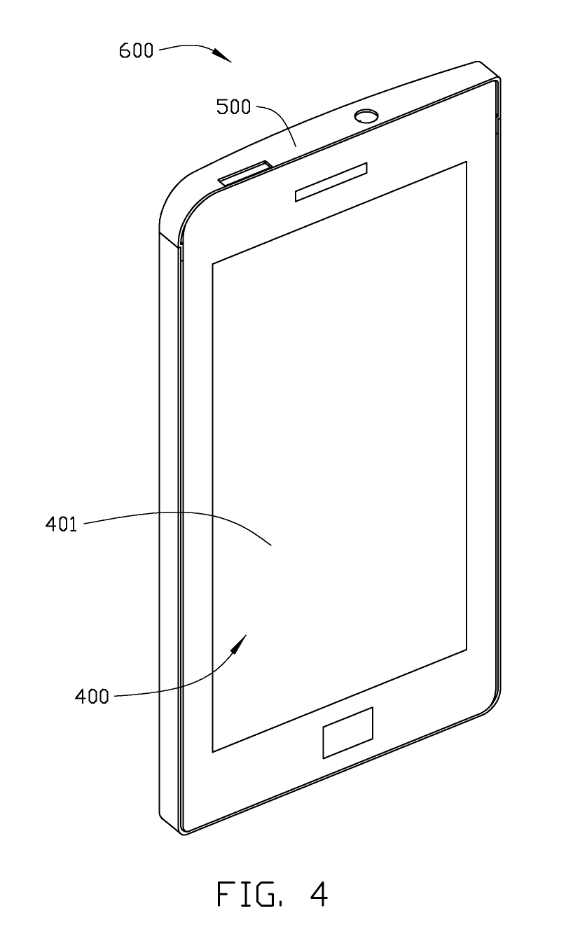

FIG. 4 illustrates a touch panel 400 and an electronic device 600 using the conductive laminate 100. The touch panel 400 includes the conductive laminate 100, a transparent panel 401 coupled to the metal layer 30 of the conductive laminate 100, an electron lead (not shown) electronically connecting the metal layer 30, and a conductive wire (not shown) electronically connecting the electron lead.

The electronic device 600 uses the above-described touch panel 400. The electronic device 600 can be a mobile phone, a tablet personal computer, or an electronic book, etc. The electronic device 600 includes a housing 500, the touch panel 400 which is mounted on the housing 500, and other electronic elements (not shown). The touch panel 400 and the housing 500 cooperatively form a receiving space (not shown), which receives the other electronic elements.

It is believed that the exemplary embodiment and its advantages will be understood from the foregoing description, and it will be apparent that various changes may be made thereto without departing from the scope of the disclosure or sacrificing all of its advantages, the examples hereinbefore described merely being preferred or exemplary embodiments of the disclosure.

What is claimed is:

1. A conductive laminate comprising:
a base layer;
an insulative layer on the base layer, and comprising a transparent and insulative adhesive;
an ink layer on the insulative layer and having a latticed structure; and
a conductive metal layer on the ink layer and having a latticed structure.

2. The conductive laminate as claimed in claim 1, wherein the base layer is made of a transparent and flexible material.

3. The conductive laminate as claimed in claim 1, wherein the insulative layer has a thickness of about 3 μm to about 50 μm, and the transparent and insulative adhesive is thermoplastic or UV-curable.

4. The conductive laminate as claimed in claim 1, wherein the ink layer is transparent and has a thickness of about 0.1 μm to about 50 μm.

5. The conductive laminate as claimed in claim 1, wherein the ink layer comprises a transparent conductive ink or a transparent non-conductive ink, the transparent conductive ink comprises at least one type of metal particles selected from the group consisting of gold particles, silver particles, copper particles, and palladium particles.

6. The conductive laminate as claimed in claim 1, wherein the metal layer comprises gold, silver, copper, palladium, nickel, and any combination thereof.

7. The conductive laminate as claimed in claim 1, wherein the metal layer has a thickness of about 0.1 μm to about 20 μm.

8. The conductive laminate as claimed in claim 1, wherein the conductive laminate is transparent.

9. A method for making a conductive laminate, comprising:
providing a base layer;
forming an insulative layer on the base layer, the insulative layer comprising a transparent and insulative adhesive;
forming an ink layer having a latticed structure on the insulative layer; and
forming a conductive metal layer having a latticed structure on the ink layer.

10. The method as claimed in claim 9, wherein the base layer is made of a transparent and flexible material.

11. The method as claimed in claim 9, wherein the ink layer comprises a transparent conductive ink, the transparent conductive ink comprises at least one type of metal particles selected from the group consisting of gold particles, silver particles, copper particles, and palladium particles; and the metal layer is formed by heating the conductive ink of the ink layer at a temperature of about 80° C. to about 200° C.

12. The method as claimed in claim 9, wherein the ink layer comprises a transparent non-conductive ink, and the metal layer is formed on the ink layer by an electroless plating process.

13. The method as claimed in claim 9, wherein the ink layer comprises a transparent ink, and the metal layer is formed on the ink layer by a vacuum deposition process.

14. The method as claimed in claim 9, wherein forming the ink layer on the insulative layer comprises:
providing a printing device comprising a first roller and a second roller, the surface of the first roller defining a plurality of interlaced grooves;
filling ink in the grooves;
rotating the first roller and the second roller relative to each other; and
passing the insulative layer coupled with the base layer through a gap between the first roller and the second roller to allow the ink in the grooves to be printed on the surface of the insulative layer.

15. A touch panel comprising:
a conductive laminate, comprising:
a base layer;
an insulative layer on the base layer and comprising a transparent and insulative adhesive;
an ink layer having a latticed structure on the insulative layer; and
a conductive metal layer having a latticed structure on the ink layer.

16. The touch panel as claimed in claim 15, wherein the base layer is made of a transparent and flexible material; the ink layer comprises a transparent ink; the metal layer comprises gold, silver, copper, palladium, nickel, or any combination thereof.

17. The touch panel as claimed in claim 15, wherein the metal layer has a thickness of about 0.1 μm to about 20 μm; the insulative layer has a thickness of about 3 μm to about 50 μm; and the ink layer has a thickness of about 0.1 μm to about 50 μm.

18. An electronic device comprising:
a touch panel, comprising:
a transparent conductive laminate, comprising:
a base layer;
an insulative layer on the base layer, and comprising a transparent and insulative adhesive;
an ink layer having a latticed structure on the insulative layer; and
a conductive metal layer having a latticed structure on the ink layer.

19. The electronic device as claimed in claim 18, wherein the base layer is made of a transparent and flexible material; the ink layer comprises a transparent ink; the metal layer is made of gold, silver, copper, palladium, nickel, and any combination thereof.

20. The electronic device as claimed in claim 18, wherein the metal layer has a thickness of about 0.1 μm to about 20 μm; the insulative layer has a thickness of about 3 μm to about 50 μm; the ink layer has a thickness of about 0.1 μm to about 50 μm.
